(19) United States
(12) Patent Application Publication
(10) Pub. No.: US 2026/0194576 A1
(43) Pub. Date: Jul. 9, 2026

(54) INSPECTION UNIT AND INSPECTION APPARATUS

(71) Applicant: OMRON Corporation, Kyoto-shi (JP)

(72) Inventors: Takahiro SAKAI, Kyoto-shi (JP); Riku YOSHIMOTO, Kyoto-shi (JP); Hiroyuki HARIMOCHI, Kyoto-shi (JP); Naoya SASANO, Kyoto-shi (JP); Minori YAHAGI, Kyoto-shi (JP)

(21) Appl. No.: 19/443,142

(22) Filed: Jan. 8, 2026

(30) Foreign Application Priority Data
Jan. 9, 2025 (JP) 2025-003584

(51) Int. Cl. G01R 31/36; G01R 31/3842; H01M 10/42

(52) U.S. Cl. CPC G01R 31/3644; G01R 31/3842; H01M 10/4285

(57) ABSTRACT

To provide an inspection unit capable of improving contact reliability between an electrode terminal of a battery and a probe pin. The inspection unit of the present disclosure is an inspection unit that comes into contact with an electrode terminal of a battery to inspect performance of the battery, the inspection unit comprising, a first probe pin; a second probe pin, an insulator that is disposed between the first probe pin and the second probe pin and electrically insulates the first probe pin and the second probe pin from each other, a socket that houses the first probe pin and the second probe pin to be movable in an axial direction, and an elastic portion that is disposed inside the socket and elastically deforms so as to move the first probe pin and the second probe pin each independently in the axial direction, wherein the second probe pin is a plate-shaped probe pin, and the elastic portion has elastic arm portions protruding from both side portions of the second probe pin in a width direction orthogonal to the axial direction and the thickness direction.

### CROSS REFERENCE TO RELATED APPLICATIONS

The present invention claims priority under 35 U.S.C. § 119 to Japanese Application No. 2025-003584, filed on Jan. 9, 2025, the entire contents of which being incorporated herein by reference.

### BACKGROUND

The present disclosure relates to an inspection unit that comes into contact with an electrode terminal of a battery to inspect performance of the battery, and an inspection apparatus including the inspection unit.

In recent years, rectangular secondary batteries capable of coping with high current (for example, 80 amperes or more), such as batteries for electric vehicles (hereinafter, referred to as EV), have been increasing. Therefore, an inspection unit capable of also handling high currents is required.

Conventionally, as this type of inspection unit, for example, an inspection unit described in Patent Literature 1 (JP 2020-26972 A) is known. Patent Literature 1 describes a configuration of a probe pin for a large current.

### SUMMARY

Conventionally, in order to measure the resistance of an electronic component with high accuracy, a Kelvin connection method (four-terminal method) has been used. According to the Kelvin connection method, the voltage applied to the electronic component can be measured without being affected by the voltage drop due to the wiring resistance or the like, and the resistance of the electronic component can be measured with high accuracy. In the Kelvin connection method, a probe pin for current measurement and a probe pin for voltage measurement are required.

The configuration of the conventional probe pin still has room for improvement from the viewpoint of improving the contact reliability between the electrode terminal of the battery and the probe pin when the rectangular secondary battery is subjected to measurement by the Kelvin connection method.

Therefore, an object of the present disclosure is to solve the above problem, and to provide a suitable inspection unit capable of improving contact reliability between an electrode terminal of a battery and a probe pin.

The inspection unit according to an aspect of the present disclosure is an inspection unit that comes into contact with an electrode terminal of a battery to inspect performance of the battery, the inspection unit including:
a first probe pin;
a second probe pin;
an insulator that is disposed between the first probe pin and the second probe pin and electrically insulates the first probe pin and the second probe pin from each other; and
a socket that accommodates the first probe pin and the second probe pin to be movable in an axial direction; and
an elastic portion that is disposed inside the socket and elastically deforms so as to move the first probe pin and the second probe pin each independently in the axial direction, wherein
the second probe pin is a plate-shaped probe pin, and
the elastic portion includes elastic arm portions protruding from both side portions of the second probe pin in a width direction orthogonal to the axial direction and the thickness direction.

An inspection apparatus according to an aspect of the present disclosure includes a plurality of inspection units according to the aspect.

The present disclosure can provide an inspection unit and an inspection apparatus capable of improving contact reliability between an electrode terminal of a battery and a probe pin.

### BRIEF DESCRIPTION OF THE DRAWINGS

These and other objects and features of the present disclosure will become clear from the following description taken in conjunction with the preferred embodiments thereof with reference to the accompanying drawings, in which:

FIG. 1 is a perspective view of an inspection unit according to a first embodiment of the present disclosure as viewed obliquely from above;

FIG. 2 is a perspective view of the inspection unit of FIG. 1 as viewed obliquely from below;

FIG. 3 is a perspective view of a socket included in the inspection unit of FIG. 1;

FIG. 4 is a perspective view illustrating a configuration in which some parts of the inspection unit of FIG. 1 are removed;

FIG. 5 is a side view of the socket of FIG. 3;

FIG. 6 is an enlarged perspective view illustrating the socket of FIG. 3 in a partial cross section;

FIG. 7 is an exploded perspective view of the socket of FIG. 3;

FIG. 8 is a plan view of a first probe pin included in the inspection unit of FIG. 1;

FIG. 9 is a plan view of a second probe pin included in the inspection unit of FIG. 1;

FIG. 10 is a plan view of an insulator included in the inspection unit of FIG. 1;

FIG. 11 is a side view illustrating a state in which a tip portion of a first probe pin included in the inspection unit of FIG. 1 is in contact with an electrode terminal of a battery;

FIG. 12 is a perspective view illustrating an example of an inspection apparatus including an inspection unit according to the first embodiment of the present disclosure;

FIG. 13 is a perspective view of a socket included in an inspection unit according to the second embodiment of the present disclosure;

FIG. 14 is an exploded perspective view illustrating a configuration in which some parts of the socket of FIG. 13 are removed;

FIG. 15 is a side view illustrating an internal structure of a first probe pin included in an inspection unit according to the second embodiment of the present disclosure;

FIG. 16 is an exploded perspective view illustrating an attachment structure of a first probe pin and an insulator included in an inspection unit according to the second embodiment of the present disclosure;

FIG. 17 is an enlarged perspective view illustrating the attachment structure of FIG. 16;

FIG. 18 is a perspective view of a socket included in an inspection unit according to a third embodiment of the present disclosure;

FIG. 19 is an exploded perspective view illustrating a configuration in which some parts of the socket of FIG. 18 are removed;

FIG. 20 is an exploded perspective view illustrating an attachment structure of a first probe pin, a second probe pin, and an insulator included in an inspection unit according to the third embodiment of the present disclosure;

FIG. 21 is an exploded perspective view illustrating an attachment structure of a first probe pin, a second probe pin, and an insulator included in an inspection unit according to a modification of the present disclosure; and

FIG. 22 is an assembled perspective view illustrating the attachment structure of FIG. 21.

### DETAILED DESCRIPTION

Hereinafter, embodiments of the present disclosure will be described with reference to the accompanying drawings. The following description is merely exemplary in nature and is not intended to limit the present disclosure, the application of the present disclosure, or the use of the present disclosure. The drawings are schematic, and ratios of dimensions and the like do not necessarily match actual ones.

In the following description, for convenience of explanation, terms indicating directions such as “upper” and “lower” are used assuming a state in normal use. However, these terms do not mean to limit a use state or the like of the inspection unit and the inspection apparatus of the present disclosure.

### First Embodiment

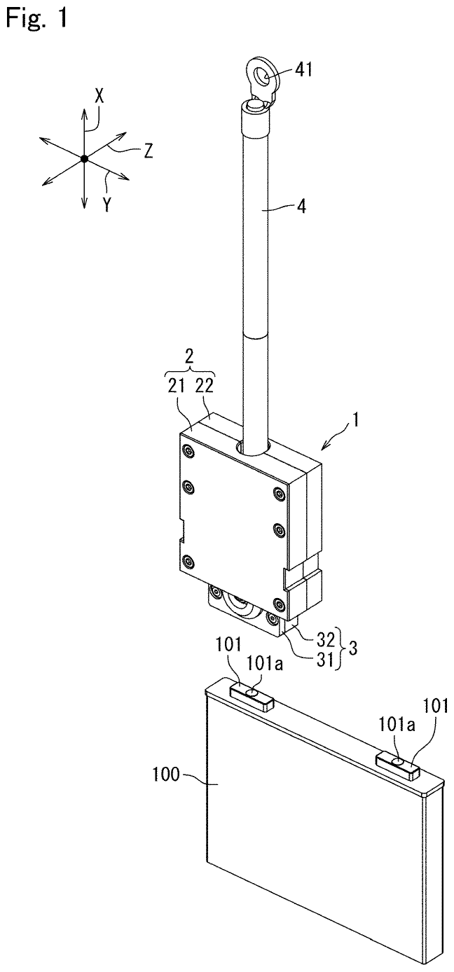

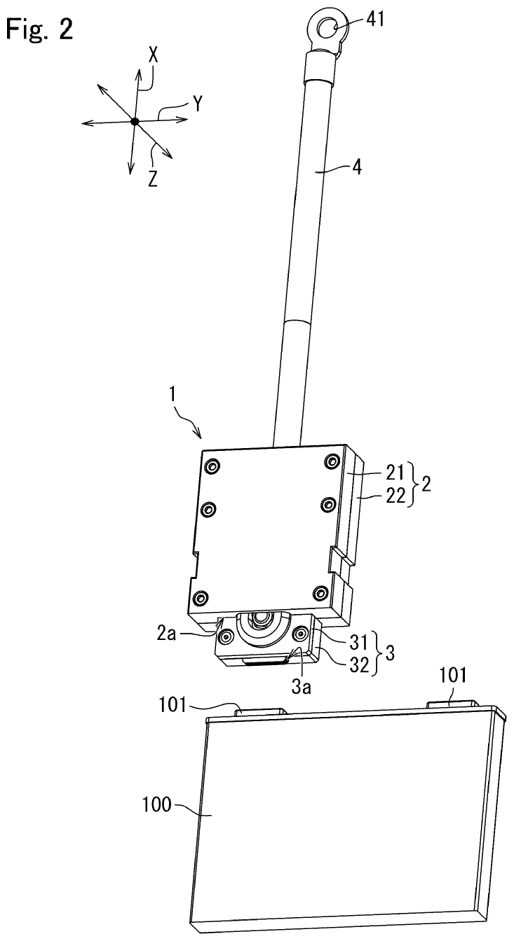

A configuration of an inspection unit according to a first embodiment of the present disclosure will be described. FIG. 1 is a perspective view of an inspection unit according to a first embodiment of the present disclosure as viewed obliquely from above. FIG. 2 is a perspective view of the inspection unit of FIG. 1 as viewed obliquely from below.

As illustrated in FIGS. 1 and 2, the inspection unit 1 according to the first embodiment is an inspection unit that comes into contact with an electrode terminal 101 of a battery 100 to inspect performance of the battery 100. In the first embodiment, the battery 100 is a rectangular secondary battery. For example, the battery 100 is a lithium ion battery for EV. The size of the battery 100 is, for example, 120 mm in height, 85 mm in width, and 12.5 mm in thickness. The inspection unit 1 is configured to perform, for example, charge and discharge inspection, energization inspection, and voltage inspection.

The battery 100 includes two electrode terminals 101. One electrode terminal 101 is a positive electrode terminal. The other electrode terminal 101 is a negative electrode terminal. In the first embodiment, the inspection unit 1 is configured to be in contact with any one of the two electrode terminals 101. A stepped portion 101a is formed in each of the two electrode terminals 101.

The inspection unit 1 includes a housing 2, a socket 3, and a cable 4.

The housing 2 has a substantially rectangular parallelepiped shape, and includes a housing cover 21 and a housing base 22. Combining the housing cover 21 and the housing base 22 forms a housing space for housing the socket 3 and the cable 4 inside the housing 2. The housing 2 is formed such that a length in the width direction Y orthogonal to the axial direction X is longer than a length in the thickness direction Z orthogonal to the axial direction X and the width direction Y.

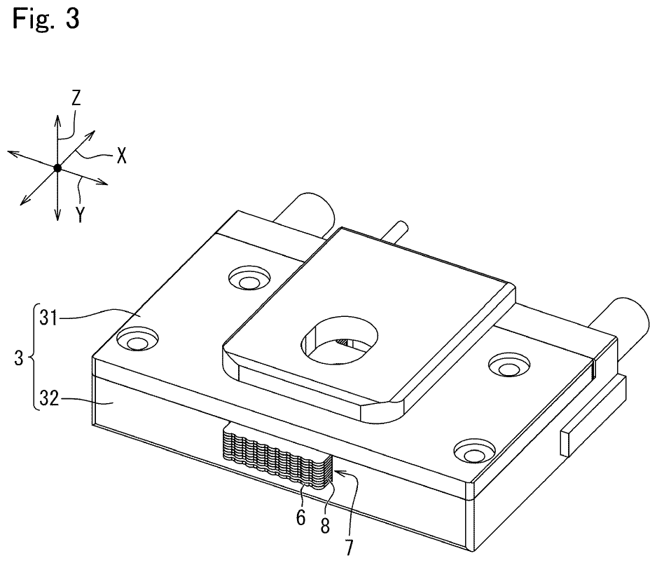

FIG. 3 is a perspective view of the socket 3.

As illustrated in FIG. 3, the socket 3 has a substantially rectangular parallelepiped shape, and includes a socket cover 31 and a socket base 32. Combining the socket cover 31 and the socket base 32 forms a housing space for housing one end of cable 4 inside the socket 3. Similarly to the housing 2, the socket 3 is formed such that the length in the width direction Y is longer than the length in the thickness direction Z.

As illustrated in FIGS. 1 and 2, the cable 4 is configured to extend in the axial direction X. One end portion of the cable 4 is held inside the socket 3. The socket 3 and the cable 4 are configured to be integrally movable with respect to the housing 2.

A round terminal 41 for electrically connecting the cable 4 to an external device is connected to the other end of the cable 4. In the first embodiment, the cable 4 is a cable having a sectional area (for example, 22SQ) through which a high current (for example, 80 amperes or more) can flow.

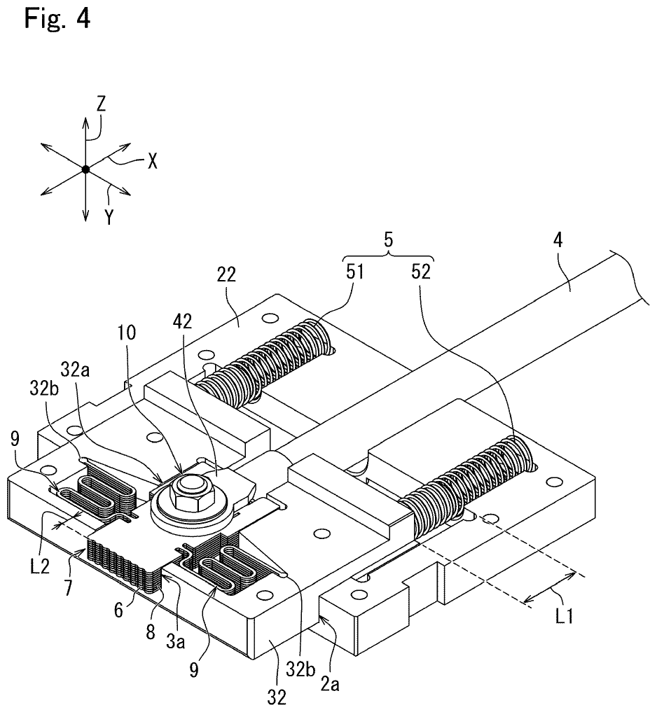

FIG. 4 is a perspective view illustrating a configuration in which a housing cover 21 and a socket cover 31 are removed from the inspection unit 1.

As illustrated in FIG. 4, a biasing member 5 that biases the socket 3 in the axial direction X is disposed inside the housing 2 such that a part of the socket 3 protrudes to the outside from the opening portion 2a provided in the housing 2. The housing 2 is configured to accommodate the socket 3 so as to be movable by a distance L1 (first distance) in the axial direction X. The distance L1 is, for example, 15 mm.

The biasing member 5 includes a first spring member 51 that biases one end side of the socket 3 in the width direction Y and a second spring member 52 that biases the other end side of the socket 3 in the width direction Y. In the first embodiment, the first spring member 51 and the second spring member 52 are composed of coil springs. The biasing forces (spring constants) of the first spring member 51 and the second spring member 52 are the same.

The socket 3 is configured to accommodate the first probe pin 6, the second probe pin 7, and the insulator 8 so as to be movable by a distance L2 (second distance) in the axial direction X. The distance L2 is, for example, 1 mm.

Inside the socket 3, an elastic portion 9 that elastically deforms so as to each independently move the first and second probe pins 6 and 7 in the axial direction X is disposed. The elastic portion 9 is in an inelastically deformed state when tip portions 6a and 7a of the first and second probe pins 6 and 7 are located at a protruding position (refer to FIG. 4) where the tip portions 6a and 7a protrude to the outside from the opening portion 3a provided in the socket 3. In addition, the elastic portion 9 is configured to be elastically deformed when the tip portions 6a and 7a of the first and second probe pins 6 and 7 move to the housing positions located inside the socket 3.

As illustrated in FIG. 4, the socket base 32 is provided with a recess portion 32a that accommodates the first probe pin 6, the second probe pin 7, and the insulator 8 in a state where the first probe pin 6, the second probe pin 7, and the insulator 8 are stacked in the thickness direction Z. The first and second probe pins 6 and 7 are configured to be movable by a distance L2 (second distance) in the axial direction X in the recess portion 32a.

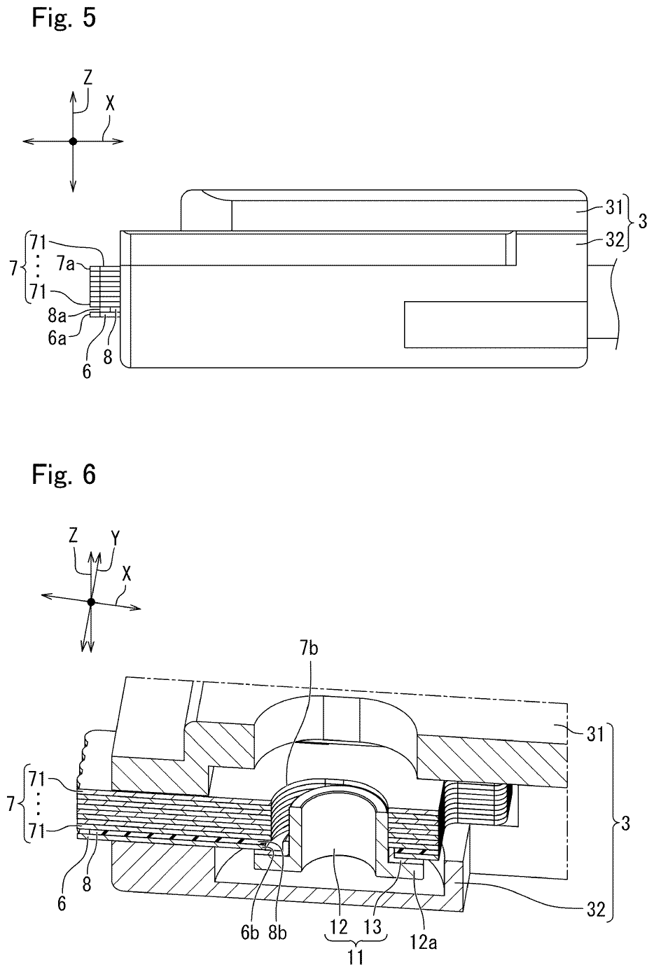

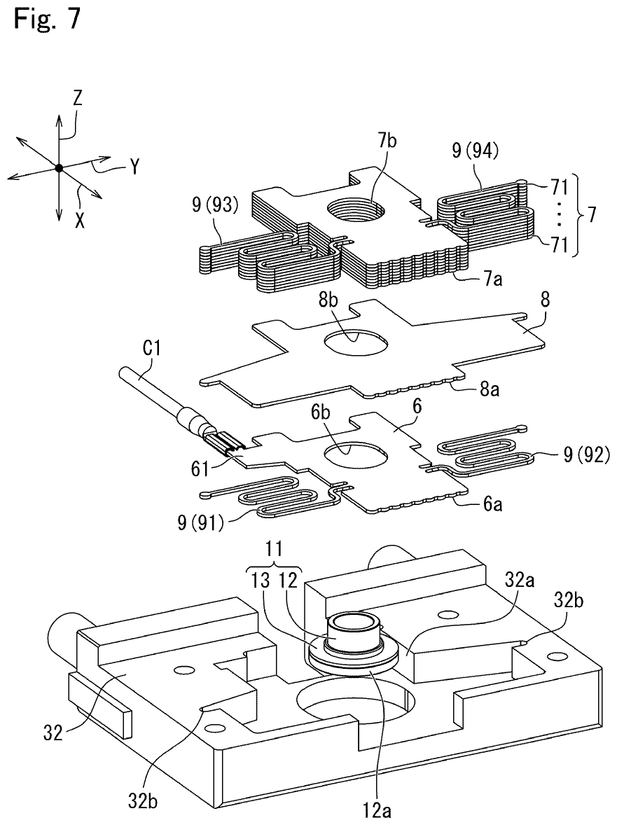

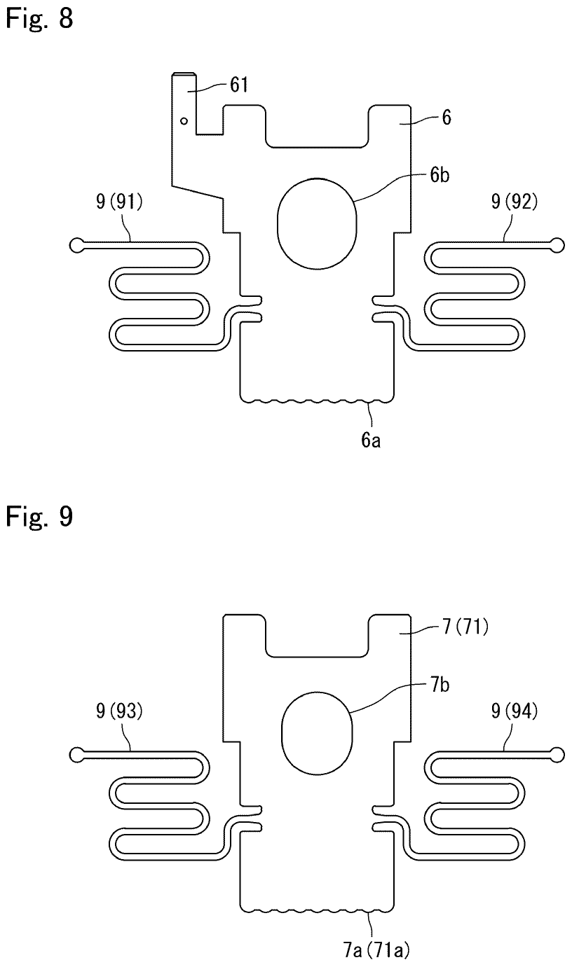

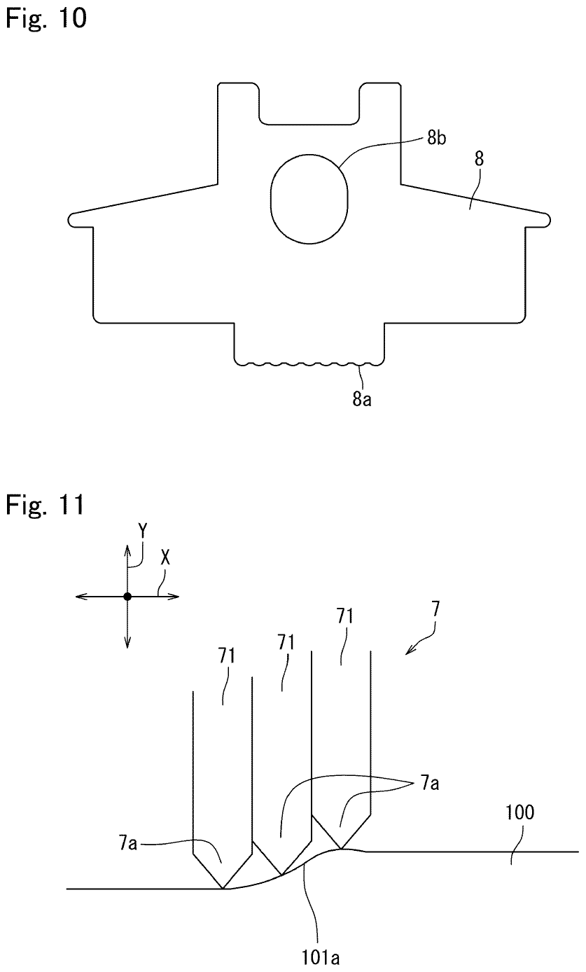

FIG. 5 is a side view of the socket 3. FIG. 6 is an enlarged perspective view illustrating the socket 3 in a partial section. FIG. 7 is an exploded perspective view of the socket 3. FIG. 8 is a plan view of the first probe pin 6. FIG. 9 is a plan view of the second probe pin 7. FIG. 10 is a plan view of the insulator 8.

As illustrated in FIGS. 5 to 7, the first and second probe pins 6 and 7 are plate-shaped probe pins, and are stacked in the thickness direction Z with the insulator 8 interposed therebetween.

The first probe pin 6 is a component for measuring a voltage, which is also called a sense pin or a signal contact, for example. The first probe pin 6 is configured by one or more conductive plates. In the first embodiment, the first probe pin 6 is configured by one metal plate. The thickness of the metal plate is, for example, 1 mm. As illustrated in FIGS. 7 and 8, the first probe pin 6 has a connection portion 61 to which a connector C1 for signal external extraction is connected. In the first embodiment, the tip portion 6a of the first probe pin 6 is formed in a wave shape in the width direction Y so as to be able to contact the electrode terminal 101 at a plurality of points as illustrated in FIG. 8.

In the first embodiment, as illustrated in FIGS. 7 and 8, the elastic portion 9 has elastic arm portions 91 and 92 protruding from both side portions of the first probe pin 6 in the width direction Y. Each tip portion of the elastic arm portions 91 and 92 is disposed in a U-shaped recess portion 32b provided in the socket base 32, and is configured to be elastically deformable in the axial direction X in the recess portion 32a. In the first embodiment, the elastic arm portions 91 and 92 are formed in a meander shape. When the first probe pin 6 is located at the housing position, the elastic arm portions 91 and 92 are elastically deformed in the axial direction X, and the first probe pin 6 comes into contact with the side wall of the recess portion 32a. As a result, further movement of the first probe pin 6 in the axial direction X is restricted. As a result, the load applied to the elastic arm portions 91 and 92 is reduced, thereby allowing excessive elastic deformation of the elastic arm portions 91 and 92 to be suppressed. In the first embodiment, the elastic arm portions 91 and 92 are integrally formed with the first probe pin 6.

The second probe pin 7 is a component for measuring a current, which is also called a Force pin or a power contact, for example. The second probe pin 7 is configured by one or more conductive plates. In the first embodiment, the second probe pin 7 is configured by a plurality of (for example, 8) metal plates 71 such that a large current (for example, 150 amperes) can flow. The thickness of each metal plate 71 is, for example, 1 mm. As illustrated in FIG. 7, the plurality of metal plates 71 are formed such that contours (outer peripheral portions) when viewed from the thickness direction Z coincide or substantially coincide with each other, in order that the metal plates can be fabricated with the same mold. In addition, when viewed from the thickness direction Z, the contour of the first probe pin 6 is formed so as to coincide or substantially coincide with the contour of the second probe pin 7, except for the vicinity of the connection portion 61.

The plurality of metal plates 71 of the second probe pin 7 each independently move in the axial direction X, whereby the tip portion 7a of each metal plate 71 can move along the stepped portion 101a of the terminal electrode 101 of the battery 100 as illustrated in FIG. 11. In addition, the first and second probe pins 6 and 7 each independently move in the axial direction X, whereby the tip portions 6a and 7a of the first and second probe pins 6 and 7 can move along the stepped portion 101a of the terminal electrode 101 of the battery 100. Conductive grease or conductive gel is applied between the metal plates 71 adjacent to each other. As a result, the metal plates 71 can each independently smoothly move in the axial direction X. In the first embodiment, the tip portion 7a of the second probe pin 7 is formed in a wave shape in the width direction Y so as to be able to contact the electrode terminal 101 at a plurality of points as illustrated in FIG. 9.

In the first embodiment, as illustrated in FIGS. 7 and 9, the elastic portion 9 has elastic arm portions 93 and 94 protruding from both side portions of the second probe pin 7 in the width direction Y. Each tip portion of the elastic arm portions 93 and 94 is disposed in a U-shaped recess portion 32b provided in the socket base 32, and is configured to be elastically deformable in the axial direction X in the recess portion 32a. In the first embodiment, the elastic arm portions 93 and 94 are formed in a meander shape. When the second probe pin 7 is located at the housing position, the elastic arm portions 93 and 94 are elastically deformed in the axial direction X, and the second probe pin 7 comes into contact with the side wall of the recess portion 32a. As a result, further movement of the second probe pin 7 in the axial direction X is restricted. As a result, the load applied to the elastic arm portions 93 and 94 is reduced, thereby allowing excessive elastic deformation of the elastic arm portions 93 and 94 to be suppressed. In the first embodiment, the elastic arm portions 93 and 94 are integrally formed with the second probe pin 7.

The elastic force of the elastic portion 9 is set to be smaller than the biasing force of the biasing member 5. That is, when a load is applied to the inspection unit 1 in the axial direction X, the elastic portion 9 is elastically deformed by the distance L2 before the biasing member 5 is compressed by the distance L1. The biasing force of the biasing member 5 is set to be, for example, 15 times or more larger than the elastic force of the elastic portion 9.

An insulator 8 is disposed between the first probe pin 6 and the second probe pin 7. The insulator 8 is configured to electrically insulate the first probe pin 6 and the second probe pin 7 from each other. In the first embodiment, the insulator 8 is a plate-shaped resin member having insulating properties. The insulator 8 has a size that encompasses the first probe pin 6 and the second probe pin 7 when viewed in the thickness direction Z. The thickness of the insulator 8 is, for example, 1 mm. The tip portion 8 a of the insulator 8 is formed in a wave shape in the width direction Y as illustrated in FIG. 10, similarly to the tip portions 6a and 7a of the first and second probe pins 6 and 7.

A round terminal 42 is connected to one end of the cable 4. The round terminal 42, the first probe pin 6, the insulator 8, and the second probe pin 7 are stacked with respect to each other in the thickness direction Z, and are clamped by the clamping member 10 having elasticity in the thickness direction Z. As a result, the round terminal 42, the first probe pin 6, the insulator 8, and the second probe pin 7 are in close contact with each other in the thickness direction Z. Conductive grease or conductive gel is applied between the first probe pin 6 and the insulator 8 and between the insulator 8 and the second probe pin 7. As a result, the first and second probe pins 6 and 7 can each independently smoothly move in the axial direction X.

As illustrated in FIGS. 6 to 11, the first probe pin 6, the second probe pin 7, and the insulator 8 have elongated holes 6b, 7b, and 8b that penetrate in the thickness direction Z and are long in the axial direction X. In the first embodiment, the elongated holes 6b, 7b, and 8b are elliptical. The elongated holes 6b and 8b are formed to be larger than the elongated hole 7b.

The clamping member 10 includes a column member 11 that is configured to be inserted into the elongated holes 6b, 7b, and 8b, electrically connected to the first probe pin 6, and electrically insulated from the second probe pin 7. In the first embodiment, the column member 11 includes a cylindrical member 12 having a flange portion 12a and an insulating ring 13 provided on a surface of the flange portion 12a facing the second probe pin 7. The cylindrical member 12 is configured by a conductor such as metal. The cylindrical member 12 comes into contact with the first probe pin 6, whereby the column member 11 is electrically connected to the first probe pin 6. The insulating ring 13 is a ring-shaped resin member having insulating properties. The insulating ring 13 is interposed between the cylindrical member 12 and the second probe pin 7, whereby the column member 11 and the second probe pin 7 are electrically insulated.

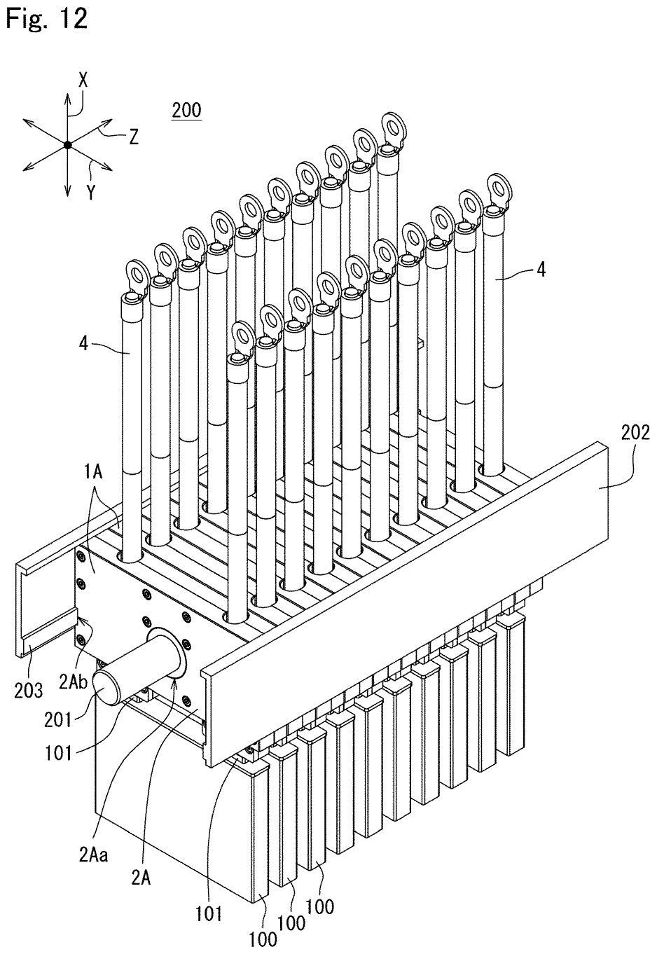

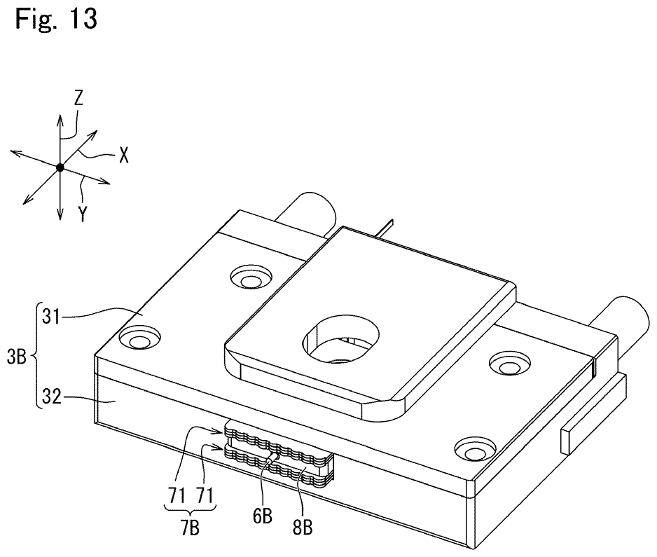

FIG. 12 is a perspective view illustrating an example of an inspection apparatus 200 including the inspection unit 1 according to the first embodiment.

The inspection apparatus 200 includes a plurality of inspection units 1, and is configured to be able to simultaneously inspect the performance of the plurality of batteries 100. In FIG. 12, the inspection apparatus 200 includes an inspection unit 1A having a housing 2A in which two inspection units 1 are disposed adjacent to each other and each housing 2 is integrated. In the inspection unit 1A, the pair of first probe pins 6 and the pair of second probe pins 7 are connected (Kelvin connection) to the two electrode terminals 101 of the battery 100. In addition, the inspection apparatus 200 includes the plurality of inspection units 1A in parallel in the thickness direction Z. The size of the housing 2A is, for example, 57 mm in height, 125 mm in width, and 13.5 mm in thickness.

A through hole 2Aa penetrating in the thickness direction Z is provided at a central portion in the axial direction X and the width direction Y of the housing 2A. A cylindrical shaft 201 is inserted into the through hole 2Aa of each inspection unit 1A. In addition, both side portions of each inspection unit 1A in the width direction Y are held by a pair of side plates 202 and 202. Groove portions 2Ab extending in the thickness direction Z are provided on two side surfaces facing each other in the width direction Y of the housing 2A of each inspection unit 1A. Each of the side plates 202 and 202 is provided with a rail 203 extending in the thickness direction Z and inserted into the groove portion 2Ab. As a result, the plurality of inspection units 1A is held at predetermined intervals in the thickness direction Z.

Then, an example of an operation of inspecting the performance of the plurality of batteries 100 using the inspection apparatus 200 will be described.

First, as illustrated in FIG. 12, the inspection apparatus 200 is disposed at a position facing the electrode terminals 101 and 101 of each battery 100.

Thereafter, each inspection unit 1A is moved in the axial direction X (downward in the drawing), and the tip portions 6a and 7a of the first and second probe pins 6 and 7 are brought into contact with the electrode terminals 101 and 101 of the corresponding battery 100. As a result, the elastic arm portions 91 and 92 of the first probe pin 6 and the elastic arm portions 93 and 94 of the second probe pin 7 are elastically deformed, and the tip portions 6a and 7a of the first and second probe pins 6 and 7 move from the protruding positions (refer to FIG. 4) to the housing positions. In this case, the first and second probe pins 6 and 7 move each independently in the axial direction X, and the tip portions 6a and 7a of the first and second probe pins 6 and 7 move along the stepped portion 101a of the terminal electrode 101 of the battery 100.

Thereafter, the biasing member 5 of each inspection unit 1A is compressed in the axial direction X. In this case, if the positions of the plurality of batteries 100 in the axial direction X are different by the distance L1 or less, each of the biasing members 5 has a compression length corresponding thereto. As a result, the tip portions 6a and 7a of the first and second probe pins 6 and 7 of all the inspection units 1A come into contact with the terminal electrodes 101 of the corresponding batteries 100. In this state, the inspection apparatus 200 performs various inspections on the plurality of batteries 100.

In the inspection units 1 and 1A according to the first embodiment, the second probe pin 7 is a plate-shaped probe pin, and the insulator 8 is disposed between the first probe pin 6 and the second probe pin 7. This configuration allows measurement for the rectangular secondary battery by the Kelvin connection method.

In addition, the inspection units 1 and 1A according to the first embodiment include the elastic arm portions 91, 92, 93, and 94 that elastically deform so as to each independently move the first and second probe pins 6 and 7 in the axial direction X. This configuration allows the first and second probe pins 6 and 7 to move so as to follow the stepped portion 101a of the electrode terminal 101. This can increase the portion in contact with the electrode terminal 101, and can improve the contact reliability between the electrode terminal 101 and the probe pin 6. In addition, the generation of the arc can be suppressed, and the durability of the probe pin 6 can be improved.

In addition, in the inspection units 1 and 1A according to the first embodiment, the elastic force of the elastic portion 9 is set to be smaller than the biasing force of the biasing member 5. This configuration allows the elastic portion 9 to have a simple structure such as the elastic arm portions 91, 92, 93, and 94 as compared with the biasing member 5.

In addition, in the inspection units 1 and 1A according to the first embodiment, the elastic portion 9 is configured to be in an inelastically deformed state when the tip portions 6a and 7a of the first and second probe pins 6 and 7 are located at the protruding positions. In addition, the elastic portion 9 is configured to be elastically deformed when the tip portions 6a and 7a of the first and second probe pins 6 and 7 move to the housing position. This configuration allows a load to be prevented from being applied to the elastic portion 9 in a state where the tip portions 6a and 7a of the first and second probe pins 6 and 7 are not in contact with the electrode terminal 101, and allows the elastic portion 9 to have a simple structure such as the elastic arm portions 91, 92, 93, and 94. In addition, when the tip portions 6a and 7a of the first and second probe pins 6 and 7 move to the housing positions, the elastic portion 9 is elastically deformed, thereby making it possible to improve contact reliability between the first and second probe pins 6 and 7 and the electrode terminal 101.

In addition, in the inspection units 1 and 1A according to the first embodiment, the first and second probe pins 6 and 7 are plate-shaped probe pins, and are stacked on each other in the thickness direction Z. In addition, the elastic portion 9 has elastic arm portions 91, 92, 93, and 94 protruding from both side portions of the first and second probe pins 6 and 7 in the width direction Y. This configuration allows the elastic portion 9 and the first and second probe pins 6 and 7 to be integrally formed, and allows the number of components to be reduced.

In addition, in the inspection units 1 and 1A according to the first embodiment, the contour of the first probe pin 6 is formed to match or substantially match the contour of the second probe pin 7 except for the vicinity of the connection portion 61 when viewed from the thickness direction Z. This configuration allows the first probe pin 6 and the second probe pin 7 to be fabricated with the same mold.

In addition, in the inspection units 1 and 1A according to the first embodiment, the first probe pin 6, the second probe pin 7, and the insulator 8 are clamped by the clamping member 10 having elasticity in the thickness direction Z. This configuration allows the first probe pin 6, the second probe pin 7, and the insulator 8 to be in close contact with each other in the thickness direction Z and to be in contact with the terminal electrode 101.

In addition, in the inspection units 1 and 1A according to the first embodiment, the first probe pin 6, the second probe pin 7, and the insulator 8 have the elongated holes 6b, 7b, and 8b that penetrate in the thickness direction Z and are long in the axial direction X. The clamping member 10 includes a column member 11 inserted into the elongated hole 6c. This configuration allows the clamping member 10 to clamp the first probe pin 6, the second probe pin 7, and the insulator 8 with a compact configuration.

In addition, in the inspection units 1 and 1A according to the first embodiment, the biasing member 5 includes the first spring member 51 that biases the one end sides of the first and second probe pins 6 and 7 in the width direction Y, and the second spring member 52 that biases the other end sides of the first and second probe pins 6 and 7 in the width direction Y. This configuration can improve contact reliability between the first and second probe pins 6 and 7 and the terminal electrode 101 in the width direction Y when the terminal electrode 101 has an inclination or a step in the width direction Y.

In addition, the inspection apparatus 200 according to the first embodiment includes the plurality of inspection units 1A. This configuration allows the plurality of batteries 100 to be simultaneously inspected, thereby allowing the total inspection time to be shortened.

### Second Embodiment

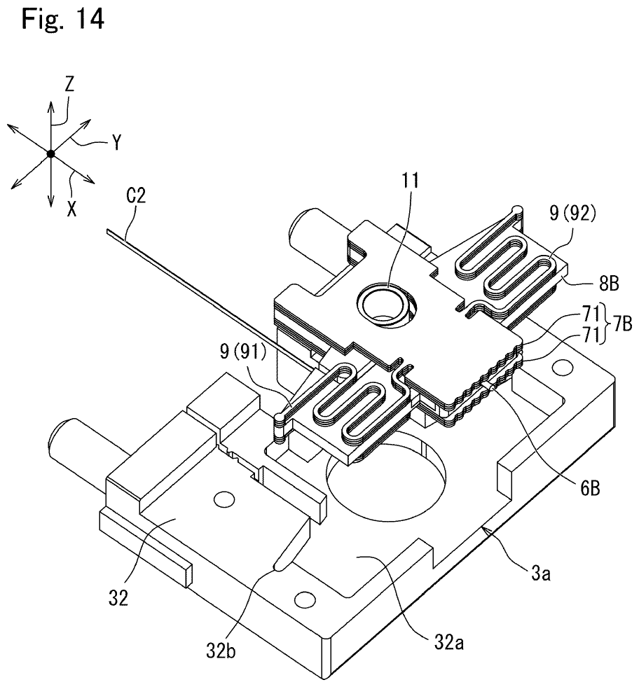

FIG. 13 is a perspective view of a socket 3B included in an inspection unit according to the second embodiment of the present disclosure. FIG. 14 is an exploded perspective view illustrating a configuration in which some parts of the socket 3B are removed. The socket 3B is different from the socket 3 according to the first embodiment in that a first probe pin 6B, a second probe pin 7B, and an insulator 8B are provided instead of the first probe pin 6, the second probe pin 7, and the insulator 8. Hereinafter, the same or similar configurations are denoted by the same reference numerals, and redundant description will be omitted.

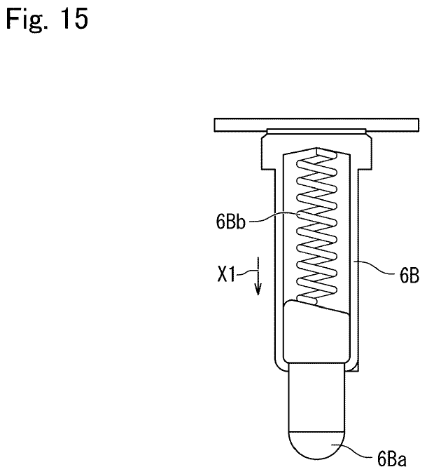

The first probe pin 6B is provided inside the insulator 8B so as to partially protrude in the axial direction X. In the second embodiment, the first probe pin 6B is a pogo pin. As illustrated in FIG. 15, the first probe pin 6B includes a spring 6Bb that biases a tip portion 6Ba in an axial direction X1. When the inspection unit is moved toward the battery 100, the tip portion 6Ba of the first probe pin 6B comes into contact with the electrode terminal 101, and the spring 6Bb is compressed. This allows the first probe pin 6B to move so as to follow the stepped portion 101a of the electrode terminal 101. That is, in the second embodiment, the spring 6Bb functions as the elastic portion 9.

The second probe pin 7B is configured by a plurality of conductor plates. More specifically, the second probe pin 7B is configured by a plurality of metal plates 71. The plurality of metal plates 71 are disposed so as to clamp the insulator 8B in the thickness direction Z. In the second embodiment, three metal plates 71 are disposed on one surface of the insulator 8B, and three metal plates 71 are disposed on the other surface of the insulator 8B.

The insulator 8B is configured to electrically insulate the first probe pin 6B and the second probe pin 7B from each other. In the second embodiment, the insulator 8B is a plate-shaped resin member having insulating properties. The insulator 8B has a size that encompasses the second probe pin 7B as viewed in the thickness direction Z. The thickness of the insulator 8B is, for example, 3 mm.

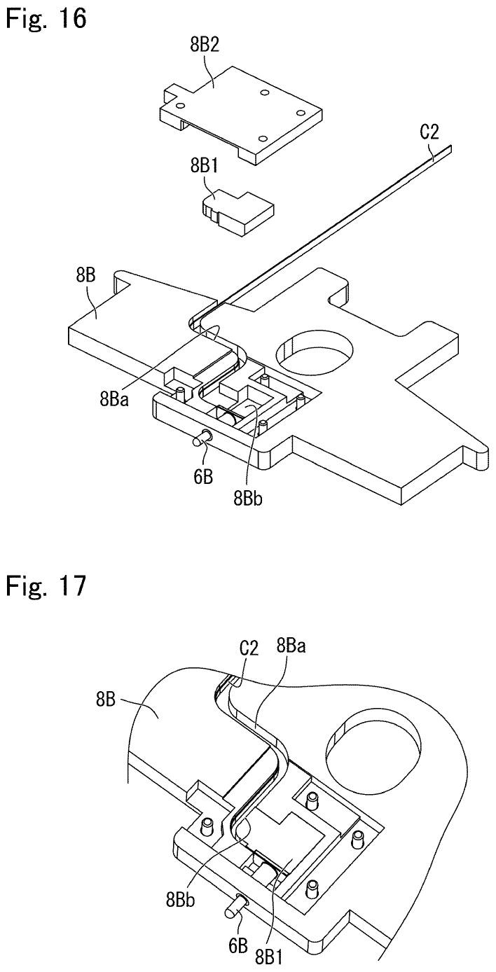

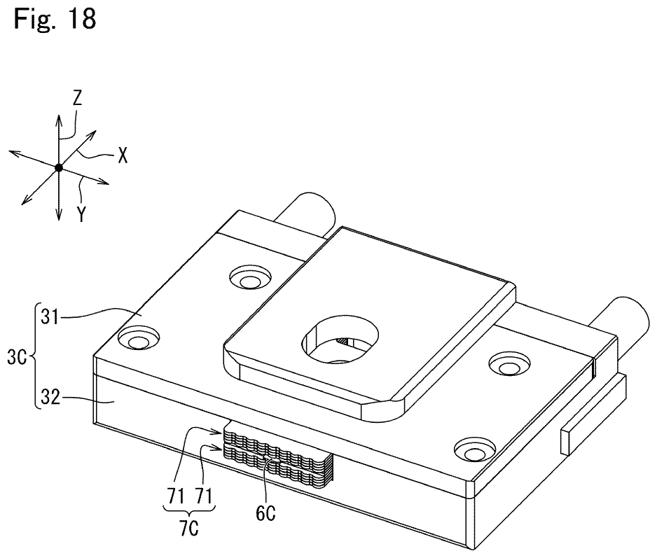

FIG. 16 is an exploded perspective view illustrating an attachment structure of the first probe pin 6B and the insulator 8B. FIG. 17 is an enlarged perspective view illustrating an attachment structure of the first probe pin 6B and the insulator 8B.

As illustrated in FIGS. 16 and 17, the insulator 8B has a groove portion 8Ba that houses the wiring board C2 for connecting the first probe pin 6B and an external device. In the second embodiment, the wiring board C2 is a flexible printed circuit board (FPC). The wiring board C2 functions as a connector for signal external extraction.

In the second embodiment, the insulator 8B is provided with a housing portion 8Bb that houses a spacer 88B1. The spacer 88B1 is housed in the housing portion 8Bb to suppress positional deviation between the first probe pin 6B and the wiring board C2. In addition, a cover 88B2 that covers the housing portion 8Bb is attached to the insulator 8B such that the spacer 88B1 is not detached from the housing portion 8Bb. The spacer 88B1 and the cover 88B2 are configured by an insulating member.

In the inspection unit according to the second embodiment, the plurality of metal plates 71 constituting the second probe pin 7B is disposed so as to clamp the insulator 8B in the thickness direction Z. This configuration allows the first probe pin 6B and the second probe pin 7B to be disposed in a well-balanced manner (for example, evenly) in the thickness direction Z, thereby allowing the contact reliability between the first and second probe pins 6B and 7B and the electrode terminal 101 to be improved.

### Third Embodiment

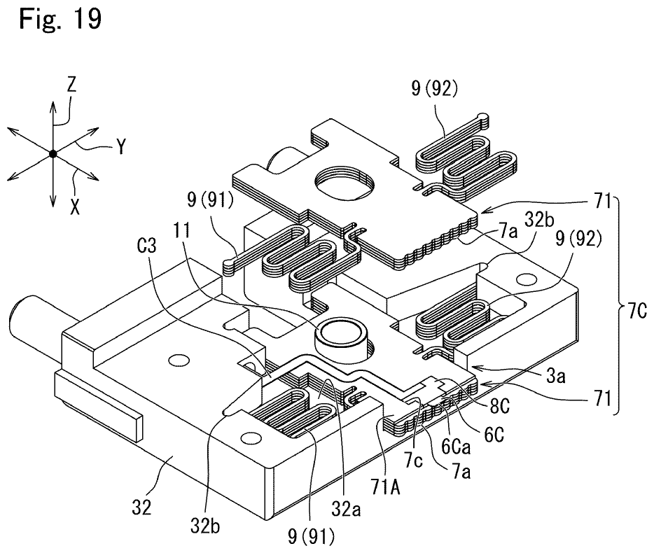

FIG. 18 is a perspective view of a socket 3C included in an inspection unit according to a third embodiment of the present disclosure. FIG. 19 is an exploded perspective view illustrating a configuration in which some parts of the socket 3C are removed. The socket 3C is different from the socket 3 according to the first embodiment in that a first probe pin 6C, a second probe pin 7C, and an insulator 8C are provided instead of the first probe pin 6, the second probe pin 7, and the insulator 8. Hereinafter, the same or similar configurations are denoted by the same reference numerals, and redundant description will be omitted.

The first probe pin 6C is provided inside the insulator 8C so as to partially protrude in the axial direction X. In the third embodiment, the first probe pin 6C is a conductor plate. More specifically, the first probe pin 6C is a metal plate. The first probe pin 6C is attached to the metal plate 71A via an insulator 8C. The thickness of the first probe pin 6C is, for example, 0.5 mm.

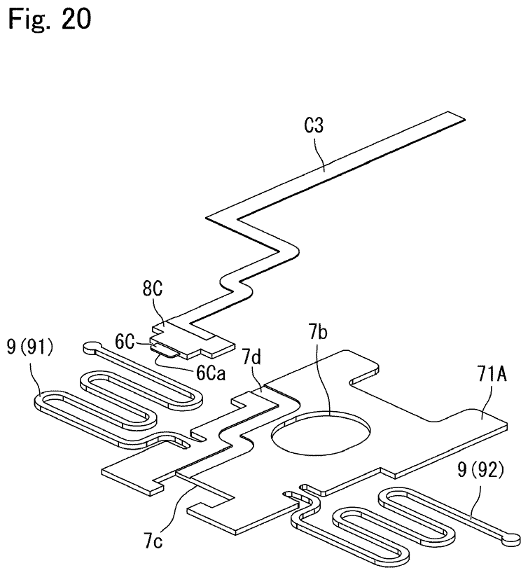

As illustrated in FIG. 20, the metal plate 71A has a recess portion 7c recessed in the axial direction X so as to house the insulator 8C. In addition, the metal plate 71A has a groove portion 7d that houses a wiring board C3 for connecting the first probe pin 6C and an external device. In the third embodiment, the wiring board C3 is a flexible printed circuit board (FPC). The wiring board C3 functions as a connector for signal external extraction. The recess portion 7c can be formed, for example, by punching a part of the metal plate 71. The groove portion 7d can be formed, for example, by cutting a part of the metal plate 71 with an end mill. The width of the groove portion 7 b is, for example, 2 mm to 3 mm. The depth of the groove portion 7 b is, for example, 0.5 mm. The metal plate 71A has a contour obtained by cutting the tip portion 7a of the metal plate 71. That is, the metal plate 71A has the same configuration and contour as those of the metal plate 71 except for the shapes of the recess portion 7c, the groove portion 7d, and the tip portion. The metal plate 71A has elastic arm portions 91 and 92.

The second probe pin 7C is configured by a plurality of conductor plates. More specifically, the second probe pin 7C is configured by the above-described metal plate 71A and the plurality of metal plates 71. The plurality of metal plates 71 are disposed so as to clamp the insulator 8C and the metal plate 71A in the thickness direction Z. In the third embodiment, four metal plates 71 are disposed on one surface of the insulator 8C and the metal plate 71A, and four metal plates 71 are disposed on the other surface of the insulator 8C and the metal plate 71A.

The insulator 8C is configured to electrically insulate the first probe pin 6C and the second probe pin 7C from each other. In the third embodiment, the insulator 8C is a plate-shaped resin member having insulating properties. The insulator 8C is formed so as to be fitted in the recess portion 7 c. The thickness of the insulator 8C is, for example, 1 mm.

When the inspection unit is moved toward the battery 100, the tip portions 6Ca and 7a of the first and second probe pins 6C and 7C come into contact with the electrode terminal 101, and the elastic arm portions 91 and 92 are elastically deformed in the axial direction X. This allows the first and second probe pins 6C and 7C to move so as to follow the stepped portion 101a of the electrode terminal 101. That is, in the third embodiment, the elastic arm portions 91 and 92 function as the elastic portion 9.

In the inspection unit according to the third embodiment, the metal plate 71A and the plurality of metal plates 71 are stacked so as to be in direct contact with each other in the thickness direction Z, thus making it possible to facilitate mutual flow of electricity.

In the inspection unit according to the third embodiment, the metal plate 71A has the same configuration and contour as those of the metal plate 71 except for the shapes of the recess portion 7c, the groove portion 7d, and the tip portion. This configuration allows the metal plate 71A and the plurality of metal plates 71 to be fabricated with the same mold.

The present disclosure is not limited to the above embodiments, and can be implemented in various other aspects. For example, in the above description, the housing 2 has a closed structure except for the opening portion 2a and the like, but the present disclosure is not limited thereto. The housing 2 may be provided with, for example, a slit or a hole for cooling the internal space.

In addition, in the above description, the inspection unit 1 includes the cable 4, but the present disclosure is not limited thereto. The inspection unit 1 may include a member capable of transmitting a current flowing through the first probe pin 6 to an external device instead of the cable 4. For example, the inspection unit 1 may include a conductor configured by a metal rod and a connector fitted to the rod.

In addition, in the above description, the inspection apparatus 200 includes the inspection unit 1A having the housing 2A in which the two inspection units 1 are disposed adjacent to each other and the housings 2 are integrated, but the present disclosure is not limited thereto. The inspection apparatus 200 may separately include a plurality of inspection units 1. As a result, for example, the battery 100 having different distances between the two electrode terminals 101 also can be inspected using the same inspection unit 1, and thus versatility can be improved.

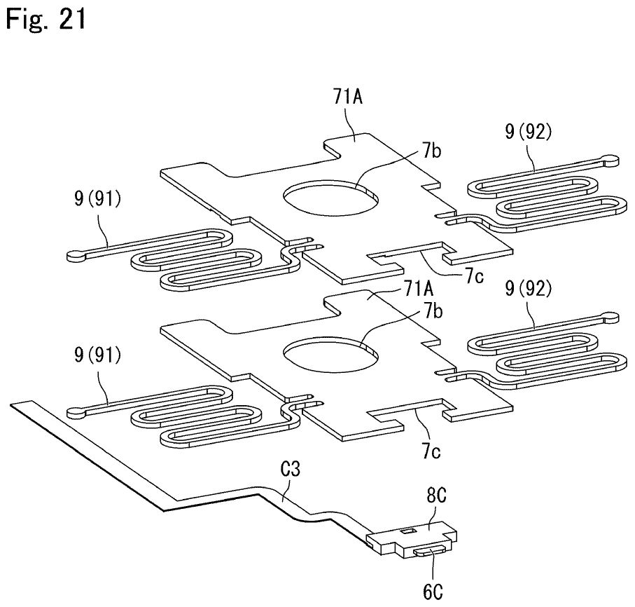

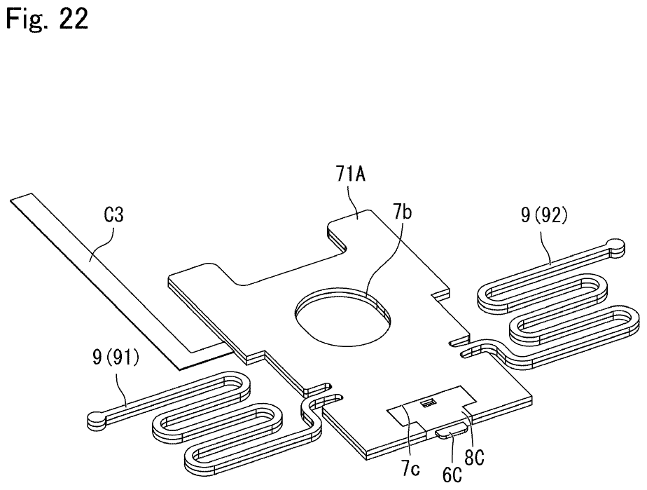

In addition, in the third embodiment, the recess portion 7c for housing the insulator 8C is provided in one metal plate 71A, but the present disclosure is not limited thereto. For example, as illustrated in FIGS. 21 and 22, the recess portion 7c recessed in the axial direction X may be provided so as to house the insulator 8C in the two metal plates 71A. This configuration can increase the thicknesses of the first probe pin 6C and the insulator 8C.

As described above, various embodiments of the present disclosure have been described in detail with reference to the drawings, and finally, various aspects of the present disclosure will be described. In the following description, as an example, reference numerals are also added.

A first aspect of the present disclosure provides an inspection unit 1 that comes into contact with an electrode terminal 101 of a battery 100 to inspect performance of the battery 100, the inspection unit including:
a first probe pin 6;
a second probe pin 7;
an insulator 8 that is disposed between the first probe pin 6 and the second probe pin 7 and electrically insulates the first probe pin 6 and the second probe pin 7 from each other;
a socket 3 that houses the first probe pin 6 and the second probe pin 7 to be movable in an axial direction X; and
an elastic portion 9 that is disposed inside the socket 3 and elastically deforms so as to move the first probe pin 6 and the second probe pin 7 each independently in the axial direction X, in which
the second probe pin 7 is a plate-shaped probe pin, and
the elastic portion 9 includes elastic arm portions 93 and 94 protruding from both side portions of the second probe pin 7 in a width direction Y orthogonal to the axial direction X and the thickness direction Z.

In the present disclosure, “protruding in the width direction” is not limited to meaning “protruding only in the width direction (linearly)”, but means “protruding in a direction including a component in the width direction”.

The second aspect of the present disclosure provides the inspection unit 1 according to the first aspect, in which
the first probe pin 6 is a plate-shaped probe pin,
the first probe pin 6 and the second probe pin 7 are stacked each other in the thickness direction Z with the insulator 8 interposed therebetween,
the first probe pin 6 has a connection portion 61 to which a connector C1 for signal external extraction is connected, and
a contour of the first probe pin 6 is formed to match or substantially match a contour of the second probe pin 7 except for a vicinity of the connection portion 61 when viewed from the thickness direction Z.

A third aspect of the present disclosure provides the inspection unit 1 according to the first or second aspect, in which
the first probe pin 6 is a plate-shaped probe pin,
the first probe pin 6 and the second probe pin 7 are stacked each other in a thickness direction Z with the insulator 8 interposed therebetween, and are clamped by a clamping member 10 having elasticity in the thickness direction Z,
the first probe pin 6, the second probe pin 7, and the insulator 8 have elongated holes 6b, 7b, and 8b that penetrate in the thickness direction Z and are long in the axial direction X, and
the clamping member 10 includes a column member 11 that is inserted into the elongated holes 6b, 7b, and 8b, is electrically connected to the second probe pin 7, but is electrically insulated from the first probe pin 6.

A fourth aspect of the present disclosure provides the inspection unit 1 according to the first aspect, in which
the second probe pin 7B is configured by a plurality of conductor plates 71,
the plurality of conductor plates 71 is disposed so as to clamp the insulator 8B in the thickness direction Z, and
the first probe pin 6B is provided inside the insulator 8B so as to partially protrude in the axial direction X.

A fifth aspect of the present disclosure provides the inspection unit according to the fourth aspect, in which
contours of the plurality of conductor plates 71 are formed to match or substantially match with each other when viewed in the thickness direction Z, and
at least one conductor plate 71A of the plurality of conductor plates 71 has a recess portion 7c recessed in the axial direction X so as to house the insulator 8C.

A sixth aspect of the present disclosure provides the inspection unit 1 according to the fifth aspect, in which
at least one conductor plate 71A of the plurality of conductor plates 71 has the groove portion 7d that houses the wiring board C2 for connecting the first probe pin 6C and an external device.

A seventh aspect of the present disclosure provides the inspection unit 1 according to the first aspect, the inspection unit further including:
a housing that houses the socket 3 so as to be movable in the axial direction; and
a biasing member 5 that is disposed inside the housing 2 and biases the socket 3 in the axial direction X such that a part of the socket 3 protrudes to the outside from the opening portion 2a provided in the housing 2.

An eighth aspect of the present disclosure provides the inspection apparatus 200 including the inspection unit according to any one of the plurality of first to seventh aspects.

Appropriately combining any embodiments or modifications among the above-described various embodiments or modifications makes it possible to achieve the respective effects. In addition, combinations of embodiments, combinations of examples, or combinations of embodiments and examples are possible, and combinations of features in different embodiments or examples are also possible.

The present disclosure has been fully described in connection with preferred embodiments with reference to the accompanying drawings, but various changes and modifications will be apparent to those skilled in the art. Such changes and modifications are to be understood as being included within the scope of the present disclosure as set forth in the appended claims.

### INDUSTRIAL APPLICABILITY

The inspection unit and the inspection apparatus of the present disclosure can improve the contact reliability between the electrode terminal of the battery and the probe pin, and thus are particularly useful as an inspection unit and an inspection apparatus used for inspecting a rectangular battery for EV.

1. An inspection unit that comes into contact with an electrode terminal of a battery to inspect performance of the battery, the inspection unit comprising:
a first probe pin;
a second probe pin;
an insulator that is disposed between the first probe pin and the second probe pin and electrically insulates the first probe pin and the second probe pin from each other;
a socket that houses the first probe pin and the second probe pin to be movable in an axial direction; and
an elastic portion that is disposed inside the socket and elastically deforms so as to move the first probe pin and the second probe pin each independently in the axial direction, wherein
the second probe pin is a plate-shaped probe pin, and
the elastic portion includes elastic arm portions protruding from both side portions of the second probe pin in a width direction orthogonal to the axial direction and the thickness direction.

2. The inspection unit according to claim 1, wherein the first probe pin is a plate-shaped probe pin;
the first probe pin and the second probe pin are stacked on each other in the thickness direction with the insulator interposed therebetween;
the first probe pin has a connection portion to which a connector for signal external extraction is connected; and
a contour of the first probe pin is formed to match or substantially match a contour of the second probe pin except for a vicinity of the connection portion when viewed from the thickness direction.

3. The inspection unit according to claim 1, wherein
the first probe pin is a plate-shaped probe pin;
the first probe pin and the second probe pin are stacked on each other in a thickness direction with the insulator interposed therebetween, and are clamped by a clamping member having elasticity in the thickness direction;
the first probe pin, the second probe pin, and the insulator have elongated holes that penetrate in the thickness direction and are long in the axial direction; and
the clamping member includes a column member that is inserted into the elongated holes and is configured to be electrically connected to the second probe pin while being electrically insulated from the first probe pin.

4. The inspection unit according to claim 1, wherein
the second probe pin is configured by a plurality of conductor plates;
the plurality of conductor plates is disposed so as to clamp the insulator in the thickness direction; and
the first probe pin is provided inside the insulator so as to partially protrude in the axial direction.

5. The inspection unit according to claim 4, wherein
contours of the plurality of conductor plates are formed to match or substantially match with each other when viewed in the thickness direction; and
at least one conductor plate of the plurality of conductor plates has a recess portion recessed in the axial direction so as to accommodate the insulator.

6. The inspection unit according to claim 5, wherein
at least one conductor of the plurality of conductor plates has a groove portion that houses a wiring board for connecting the first probe pin and an external device.

7. The inspection unit according to claim 1, further comprising:
a housing that houses the socket to be movable in the axial direction; and
a biasing member that is disposed inside the housing and biases the socket in the axial direction such that a part of the socket protrudes to the outside from an opening portion provided in the housing.

8. An inspection apparatus comprising a plurality of the inspection units according to claim 1.
